(19) United States
(12) Patent Application Publication
(10) Pub. No.: US 2009/0008633 A1
(43) Pub. Date: Jan. 8, 2009

(54) NONVOLATILE MEMORY DEVICE USING CONDUCTIVE ORGANIC POLYMER HAVING NANOCRYSTALS EMBEDDED THEREIN AND METHOD OF MANUFACTURING THE NONVLATILE MEMORY DEVICE

(75) Inventors: Jea-Gun Park, Gyenggi-do (KR); Ungyu Paik, Seoul (KR); Hyun-Min Seung, Seoul (KR); Sangkyu Lee, Seoul (KR); Byeong-Il Han, Busan (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/108,590

(22) Filed: Apr. 24, 2008

(30) Foreign Application Priority Data
Apr. 25, 2007 (KR) 10-2007-0040520
Apr. 25, 2007 (KR) 10-2007-0040521

(51) Int. Cl. H01L 51/00; H01L 51/40

(52) U.S. Cl. 257/40; 438/99; 257/E51.035; 257/E51.001

(57) ABSTRACT

A nonvolatile memory device and a method of manufacturing the same are provided. The nonvolatile memory device which is convertible among a high current state, an intermediate current state, and a low current state, said device includes upper and lower conductive layers; a conductive organic layer comprising a conductive organic polymer and which is formed between the upper and lower conductive layers and has a bistable conduction property; and nanocrystals are formed in the conductive organic layer. The conductive organic polymer may be poly-N-vinylcarbazole (PVK) or polystyrene (PS). The method is characterized in that a conductive organic layer is formed by applying a conductive organic material such as PVK or PS using spin coating. Therefore, it is possible to provide a highly-integrated memory device that consumes less power and provides high operating speed. In addition, it is possible to provide the thermal stability of a memory device by using a conductive organic polymer. Moreover, it is possible to reduce the time required to deposit a conductive organic layer by forming a conductive layer using spin coating. Furthermore, it is possible to form a conductive organic layer in various shapes by using mask patterns that can be formed on a substrate in various shapes.

### CROSS-REFERENCE TO RELATED APPLICATION

This application claims priority from Korean Patent Application Nos. 10-2007-040520 and 10-2007-040521 each filed on Apr. 25, 2007 in the Korean Intellectual Property Office, the disclosures of which are incorporated herein by reference in their entireties.

### BACKGROUND OF THE INVENTION

The present invention relates to a nonvolatile memory device and a method of manufacturing the same, and more particularly, to a nonvolatile memory device using a conductive organic material that can provide two different conductive states at the same voltage and a method of manufacturing the same.

Memory devices are largely classified into volatile memory devices such as dynamic random access memory (DRAM) devices and nonvolatile memory devices such as flash memory devices.

A DRAM forms a channel between source and drain terminals by adjusting the channel width under a gate in response to a voltage applied to the gate, and charges or discharges a capacitor connected thereto. Thereafter, the DRAM classifies the charge or discharge state of the capacitor as a data value of 0 or 1. However, a DRAM needs to continuously charge a capacitor and generally consumes a considerable amount of power because of a high probability of data loss caused by a leakage current.

A flash memory often causes Fowler-Nordheim (F—N) tunneling in response to a voltage applied to a control gate and a channel region, varies the amount of charge in a floating gate, and measures the threshold voltage of a channel. Then, the flash memory classifies the threshold voltage of the channel as a data value of 0 or 1. However, a flash memory may cause a considerable increase in voltage used therein due to the use of F—N tunneling. Further, the data processing speed of a flash memory is generally low since a flash memory reads or writes data in a predetermined order.

In order to provide such conventional memory devices, a minimum of hundreds to thousands of processes may need to be performed, which reduces the manufacturing yield. In addition, dozens to thousands of patterns including gates, sources and drains may need to be formed, which makes it difficult to increase the integration density of memory devices.

In order to address the problems associated of DRAMs or flash memories and provide next-generation memory devices having the benefits of DRAMs and flash memories, various research has long been conducted.

The field of research of next-generation memory devices may be divided according to the material of which memory cells are made up. Many efforts have been made to store data using various materials. Exemplary materials include materials that become either crystalline or amorphous when a current is applied thereto, a ferroelectric material that polarizes itself when power is applied, a ferromagnetic material, and a conductive organic material.

However, it is necessary to optimize processing conditions for applying such materials to manufacture highly-integrated memory devices.

The use of conductive organic materials has not yet been widespread in manufacturing memory devices. A drawback to their use is that it is difficult to determine optimum processing conditions to manufacture memory device using conductive organic materials.

Further, low-molecular weight conductive organic materials, which have been widely used to manufacture conventional memory devices, are vulnerable to heat and are thus often likely to result in breakdown of the properties of memory devices, especially when the memory devices are operated at a temperature above 200° C.

### SUMMARY OF THE INVENTION

Aspects of the present invention provide a conductive organic nonvolatile memory device which causes no data loss even when being powered off, consumes less power, contributes high integration density and which provides high operating speed, and a method of manufacturing the conductive organic nonvolatile memory device.

Aspects of the present invention also provide a nonvolatile memory device and a method of manufacturing the same, in which the bistable conduction property of an organic material may be maintained by establishing optimum processing conditions and the thermal stability of a nonvolatile memory device may also be maintained by using a conductive organic material having the properties of a polymer.

However, the aspects of the present invention are not restricted to those set forth herein. The above and other aspects of the present invention will become more apparent to one of ordinary skill in the art to which the present invention pertains by referencing a detailed description of the present invention given below.

According to an aspect of the present invention, there is provided a nonvolatile memory device which is convertible among a high current state, an intermediate current state, and a low current state, said device including: upper and lower conductive layers; a conductive organic layer comprising a conductive organic polymer and which is formed between the upper and lower conductive layers and has a bistable conduction property; and nanocrystals are formed in the conductive organic layer.

The conductive organic polymer may be poly-N-vinylcarbazole (PVK) or polystyrene (PS).

The nanocrystals may include at least one of Au, Pt, Ag, Ni, Cu and an alloy thereof.

The upper and lower conductive layers may intersect each other, and the nanocrystals may be dispersed in the overlapping area of the upper and lower conductive layers.

The nonvolatile memory device may realize multi-level cells (MLCs).

According to another aspect of the present invention, there is provided a method of manufacturing a nonvolatile memory device, the method including: forming a lower conductive layer on a substrate; forming a conductive organic layer having nanocrystals dispersed therein on the substrate using spin coating, for example; and forming an upper conductive layer on the conductive organic layer. The method further comprises dispersing the nanocrystals in the conductive organic layer before the forming of the conductive layer.

The forming the conductive organic layer, may include: forming mask patterns on the substrate; applying a conductive organic material having the nanocrystals dispersed therein on the substrate using spin coating; and removing the mask patterns and portions of the conductive organic material on the mask patterns.

The applying the conductive organic material, may include applying a liquid-phase conductive organic material on the substrate while rotating the substrate at 1000-3000 rpm.

The applying the conductive organic material, may include applying a liquid-phase conductive organic material on the substrate and then rotating the substrate at 1000-3000 rpm.

The conductive organic material may be PVK or PS mixed with a solvent.

### BRIEF DESCRIPTION OF THE DRAWINGS

FIG. 1 illustrates a cross-sectional view of a nonvolatile memory device according to an embodiment of the present invention;

FIG. 2 shows a transmission electron microscope (TEM) image of the nonvolatile memory device shown in FIG. 1;

FIG. 3 illustrates an enlarged view of a circled portion of FIG. 2;

FIGS. 4, 5A through 5G and 6 illustrate graphs of the nonvolatile memory device shown in FIG. 1;

FIG. 7 illustrates a graph of the data retention capability of the nonvolatile memory device shown in FIG. 1;

FIGS. 8 through 11 illustrate diagrams of a method of manufacturing a nonvolatile memory device according to an embodiment of the present invention;

FIG. 12 illustrates a TEM image of a memory device obtained by the method of the embodiment of FIGS. 12 through 18; and

FIGS. 13A through 13D illustrate energy dispersive spectroscopy (EDS) images of the distributions of various components of the memory device illustrated in FIG. 19;

### DETAILED DESCRIPTION OF THE EXEMPLARY EMBODIMENTS

The present invention will now be described more fully with reference to the accompanying drawings, in which exemplary embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to those skilled in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout. As used herein the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Furthermore, relative terms such as “below,” “beneath,” or “lower,” “above,” and “upper” may be used herein to describe one element's relationship to another element as illustrated in the accompanying drawings. It will be understood that relative terms are intended to encompass different orientations of the device in addition to the orientation depicted in the accompanying drawings. For example, if the device in the accompanying drawings is turned over, elements described as being on the “lower” side of other elements would then be oriented on “upper” sides of the other elements. Similarly, if the device in one of the figures is turned over, elements described as “below” or “beneath” other elements would then be oriented “above” the other elements. Therefore, the exemplary terms “below” and “beneath” can, therefore, encompass both an orientation of above and below.

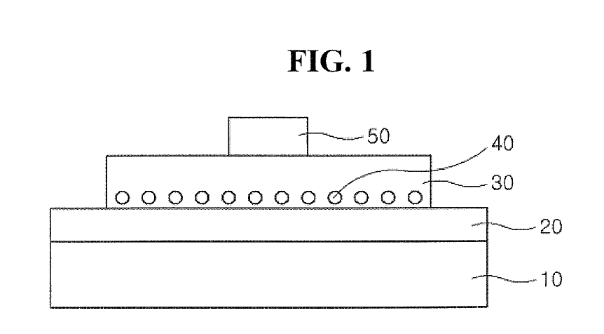

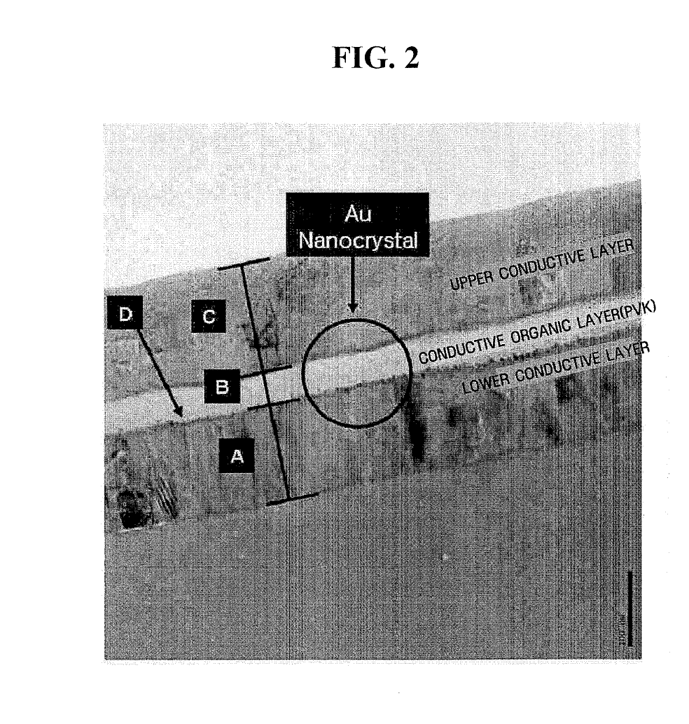

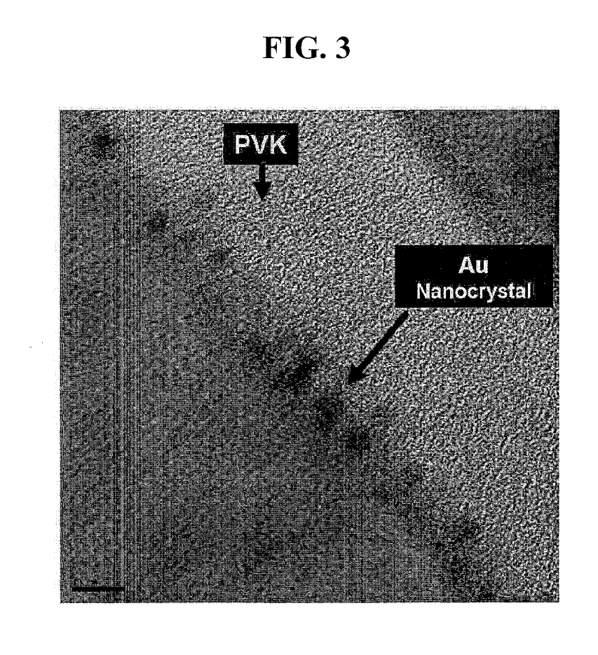

FIG. 1 illustrates a cross-sectional view of a nonvolatile memory device according to an embodiment of the present invention; FIG. 2 shows a transmission electron microscope (TEM) image of the nonvolatile memory device illustrated in FIG. 1; FIG. 3 illustrates an enlarged view of a nanocrystal layer of FIG. 2; FIGS. 4, 5A through 5G and 6 illustrate graphs of the nonvolatile memory device illustrated in FIG. 1; and, FIG. 7 illustrates a graph of the data retention capability of the nonvolatile memory device illustrated in FIG. 1 Referring to FIG. 2, reference character A indicates a lower conductive layer, reference characters B and C indicate conductive organic layers, and D indicates an upper conductive layer.

Referring to FIGS. 1 through 7, the nonvolatile memory device may include lower and upper conductive layers 20 and 50, a conductive organic layer 30, which may be interposed between the lower and upper conductive layers 20 and 50 and may have a bistable conduction property, and nanocrystals 40 which may be distributed in the conductive organic layer 30. Examples of the nanocrystals 40 include Au nanocrystals, as indicated by FIGS. 2 and 3.

The conductive organic layer 30 may be formed of a polymer material whose properties include conductive properties that do not change even at high temperatures (i.e., at a temperature of 300° C. or higher). The conductive organic layer 30 may have a multilayer structure, and the nanocrystals 40 may be formed in the multilayer structure of the conductive organic layer 30. That is, for example, referring to FIG. 1, the lower conductive layer 20 is formed on a substrate 10, the conductive organic layer 30 is formed on the lower conductive layer 20, the nanocrystals 40 are formed in the conductive organic layer 30, and the upper conductive layer 50 is formed on the conductive organic layer 30. The nanocrystals 40 may be dispersed in the bottom of the conductive organic layer 30. In the meantime, the conductive organic layer 30 may comprise the first and second conductive organic layers. The first and second conductive organic layers may be interposed between the lower and upper conductive layers 20 and 50, and the nanocrystals 40 may be interposed between the first and second conductive organic layers.

The substrate 10 may be an insulating substrate, a semiconductor substrate or a conductive substrate. More specifically, the substrate 10 may be a plastic substrate, a glass substrate, an Al₂O₃ substrate, a SiC substrate, a ZnO substrate, a Si substrate, a GaAs substrate, a GaP substrate, a LiAl₂O₃ substrate, a BN substrate, an AlN substrate, a silicon-on-insulator (SOI) substrate or a GaN substrate. Alternatively, the substrate 10 may be a conductive substrate. In this case, the substrate 10 may need to be isolated from the lower conductive layer 20 by a dielectric material. Alternatively, the substrate 10 may be a silicon (Si) substrate on which an oxide layer (SiO₂) is deposited.

The lower and upper conductive layers 20 and 50 may be formed of nearly all materials having electric conductivity. For example, the lower and upper conductive layers 20 and 50 may be formed of Au, Pt, Ag, Ni, Cu or an alloy thereof.

The conductive organic layer 30 may be formed of poly-N-vinylcarbazole (PVK) or polystyrene (PS). Alternatively, the conductive organic layer 30 may be formed of 2-amino-4,5-imidazoledicarbonitrile (AIDCN), naphthyl phenyldiamine (α-NPD) or tris-(8-hydroxyquinoline) aluminum (Alq₃).

PVK, sometimes represented as PNVC, PVCa or PVCz, is represented by Chemical Formula (1):

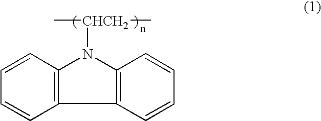

wherein n is an integer of one or greater than one.

PS is represented by Chemical Formula (2):

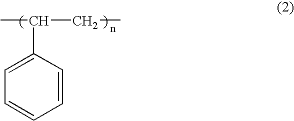

wherein n is an integer of one or greater than one.

Conductive organic materials such as PVK and PS may have a bistable conduction property, i.e., have two different conductivities at the same voltage. In addition, conductive organic materials such as PVK and PS may be used even at a temperature of 300° C. or higher. Thus, it may be possible to increase the processing temperature of a memory device and prevent the conductive organic properties of a memory device from breaking down at a temperatures of 300° C. and higher, such as during a passivation operation.

The nanocrystals 40 may be formed of Au, Pt, Ag, Cu, Ti, Ni or an alloy thereof. That is, it may be possible to uniformly form and disperse quantum dots having a uniform size in the conductive organic layer 30 by using a metal that minimally oxidizes. The nanocrystals 40 may be formed of Au and/or Ag. Further, nanocrystals 40 may be spaced apart from each other.

The operation of the nonvolatile memory device illustrated in FIG. 1 will hereinafter be described in detail with reference to FIGS. 4 through 7.

Referring to FIG. 1, the nonvolatile memory device includes the lower and upper conductive layers 20 and 50, the conductive organic layer 30, and the nanocrystals 40, which are distributed in the conductive organic layer 30. When a voltage is applied to the lower and upper conductive layers 20 and 50, the nonvolatile memory device may have various currents Iₒₙ, I_{off}, and Iᵢₙₜₑᵣ in response to a certain range of voltages (Vᵣ=2 V where Vᵣ indicates a read voltage), as illustrated in FIG. 4.

The first, second and third currents Iₒₙ, Iᵢₙₜₑᵣ and I_{off} respectively correspond to a high-current (low-resistance) state that occurs at the read voltage Vᵣ after the application of a write voltage Vₚ, an intermediate current (intermediate-resistance) state that occurs at the read voltage Vᵣ after the application of a negative differential resistance (NDR) voltage V_{NDR}, and a low-current (high-resistance) state that occurs at the read voltage Vᵣ after the application of an erase voltage Vₑ.

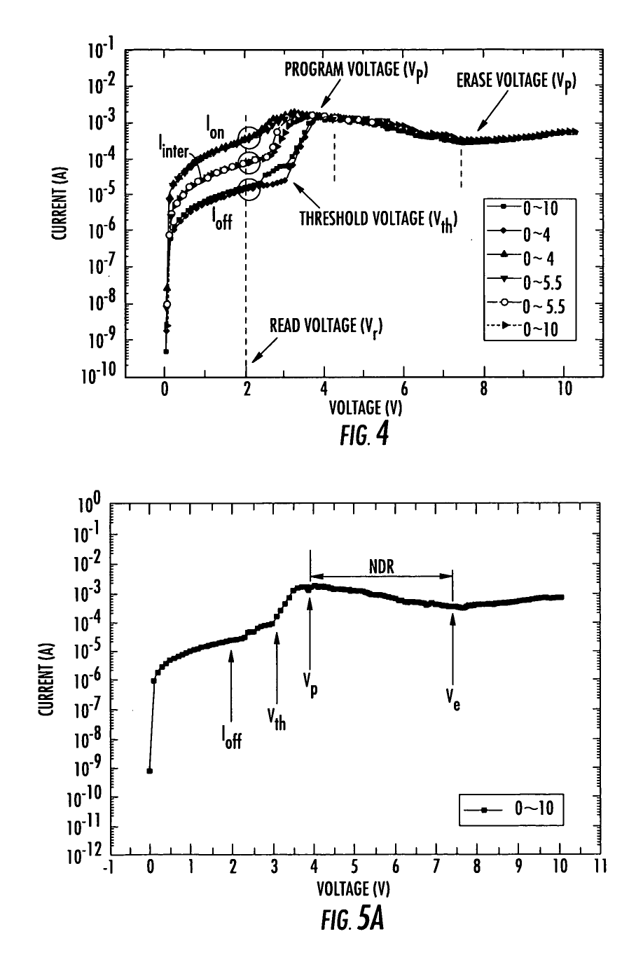

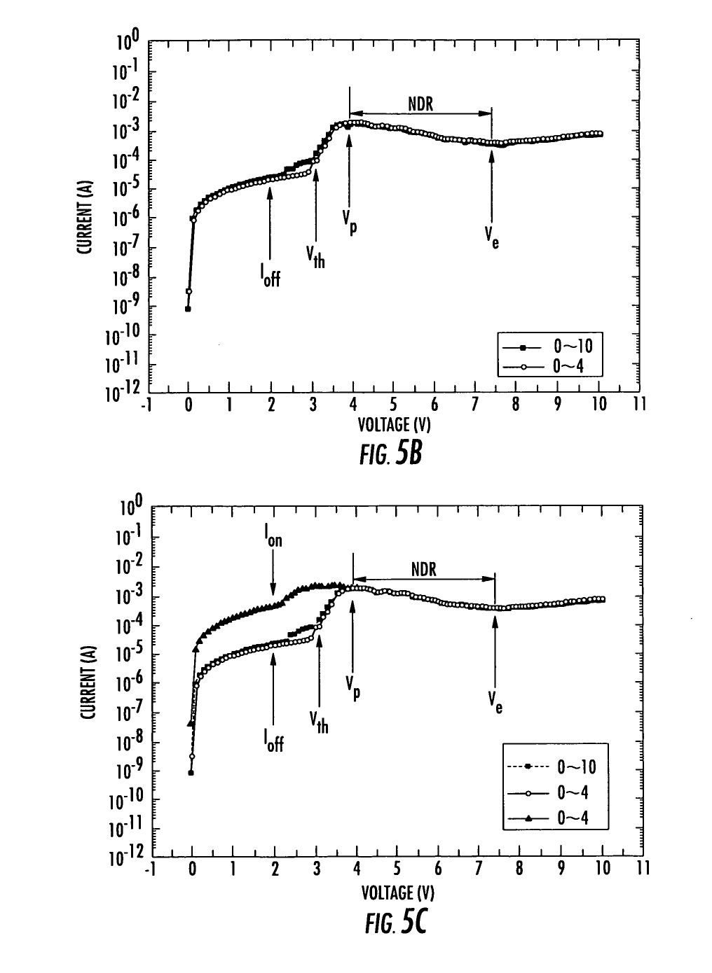

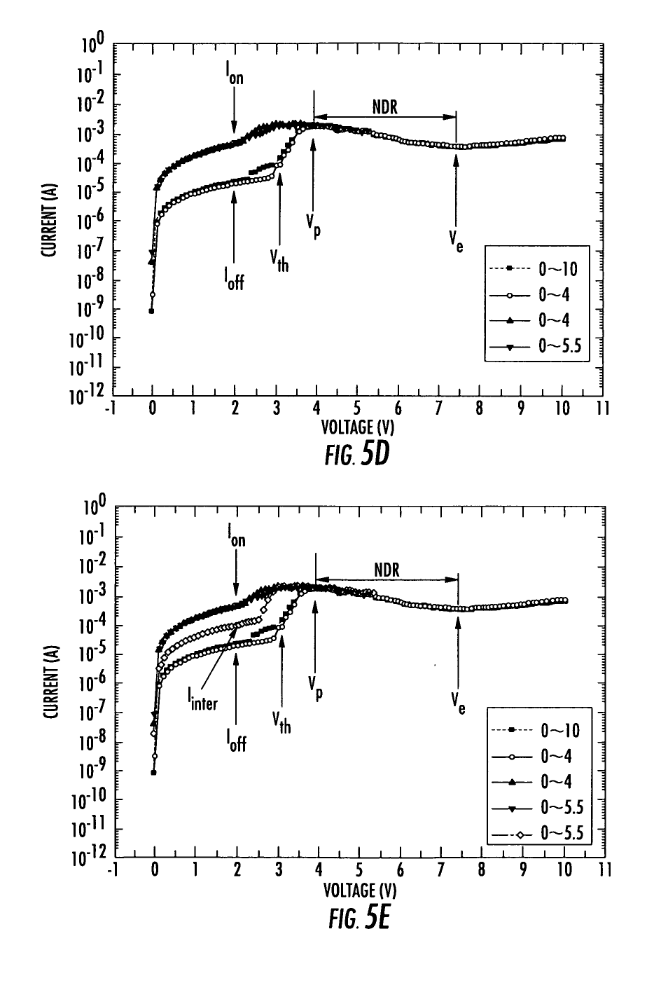

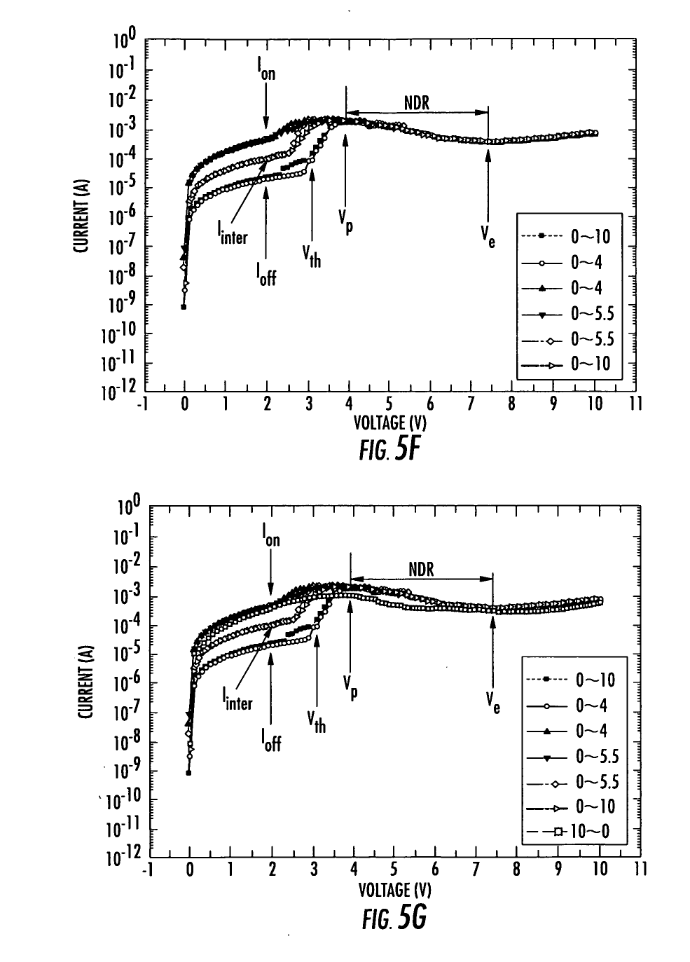

If the lower conductive layer 20 is connected to a ground, the upper conductive layer 50 is connected to a predetermined voltage source, and the voltage of the voltage source is continually increased toward a positive direction, the current of the nonvolatile memory device slowly increases until a threshold voltage Vₜₕ or a voltage higher than the threshold voltage Vₜₕ is applied. Thereafter, if the threshold voltage Vₜₕ is applied, the current of the nonvolatile memory device rapidly increases until the voltage of the nonvolatile memory device reaches the write voltage Vₚ. Thereafter, if a voltage higher than the threshold voltage Vₜₕ is applied, an NDR state may occur, and the voltage of the nonvolatile memory device may reach the erase voltage Vₑ. Thereafter, the current of the nonvolatile memory device increases again according to a voltage applied to the nonvolatile memory device, as illustrated in FIG. 5A.

If the voltage of the upper conductive layer 50 is continually increased from 0 V to the write voltage Vₚ toward the positive direction, as illustrated in FIG. 5B, and then continually increased again from 0 V to the write voltage Vₚ toward the positive direction, charge may accumulate on the surface of the nanocrystals 40, and thus, the current of the nonvolatile memory device may increase and may thus be placed in the high-current state (Iₒₙ), as illustrated in FIG. 5C. Thereafter, if the voltage of the upper conductive layer 50 is continually increased from 0 V to the NDR voltage V_{NDR} toward the positive direction, the nonvolatile memory device may reach an NDR region, as illustrated in FIG. 5D. Thereafter, if the voltage of the upper conductive layer 50 is continually increased again from 0 V to the voltage V_{NDR} toward the positive direction, a new current path, i.e., the path of the current Iᵢₙₜₑᵣ, may appear, as illustrated in FIG. 5E. Thereafter, if the voltage of the upper conductive layer 50 is continually increased from 0 V to the erase voltage Vₑ toward the positive direction, the current Iᵢₙₜₑᵣ may flow in the nonvolatile memory device, and the charge accumulated on the nanocrystals 40 may be erased while the voltage of the nonvolatile memory device is increased up to the erase voltage Vₑ through the write voltage Vₚ and the NDR voltage V_{NDR}, as illustrated in FIG. 5F. Thereafter, if the write voltage Vₚ, the NDR voltage V_{NDR}, the erase voltage Vₑ, and a voltage of 0V are applied to the nonvolatile memory device, charge may accumulate again on the nanocrystals 40, and thus, the nonvolatile memory device may be placed in the high-current state (Iₒₙ), as illustrated in FIG. 5G.

If the nanocrystals 40 are yet to be charged with carriers due to the difference between the energy level of the nanocrystals 40 and the energy level of the conductive organic layers 30 and 50, the nonvolatile memory device may be placed in the low-current state (I_{off}), i.e., the current of the nonvolatile memory device may slightly increase according to a voltage applied thereto, until the threshold voltage Vₜₕ is applied to the nonvolatile memory device. However, if the threshold voltage Vₜₕ or a voltage higher than the threshold voltage Vₜₕ is applied to the conductive organic layers 30 and 50, the nanocrystals 40 may be charged with carriers, and thus the current of the nonvolatile memory device may rapidly increase. The current of the nonvolatile memory device may be dozens to thousands of times higher when the nanocrystals 40 are charged with carriers than when the nanocrystals 40 are yet to be charged with carriers. If the NDR voltage V_{NDR} is applied to the conductive organic layers 30 and 50, the nanocrystals 40 may be partially discharged or may be partially charged with carriers. Thus, the current of the nonvolatile memory device may become lower than the first current Iₒₙ and higher than the third current I_{off}. If a voltage higher than the NDR voltage V_{NDR}, i.e., the erase voltage Vₑ, is applied to the conductive organic layers 30 and 50, the nanocrystals 40 may be completely discharged.

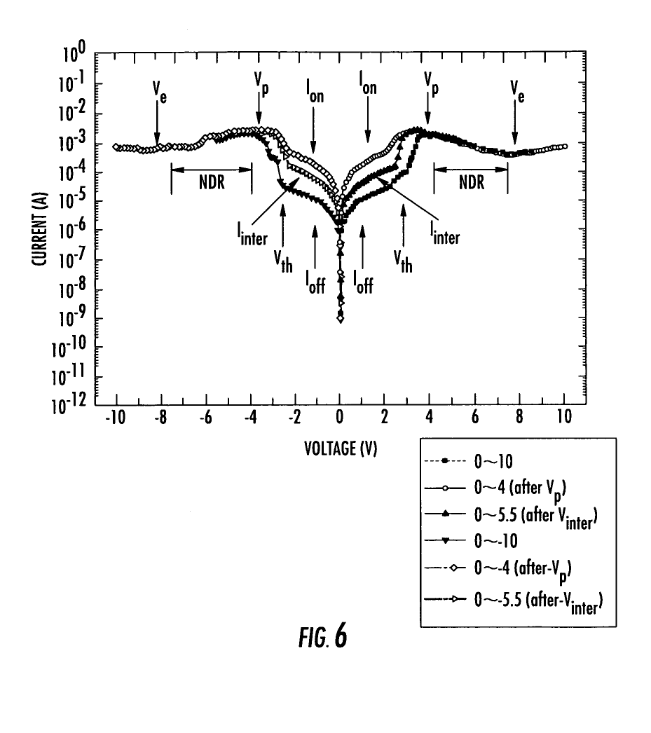

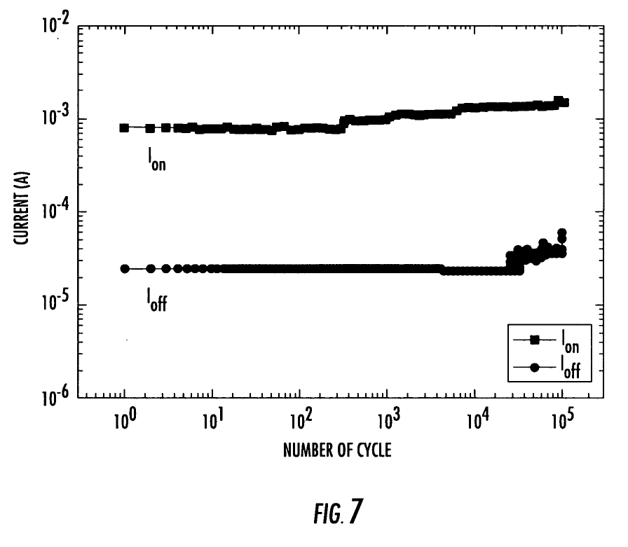

If the voltage of the predetermined voltage source is continually increased toward a negative direction, the current of the nonvolatile memory device may slowly increase until the voltage of the nonvolatile memory device reaches the threshold voltage Vₜₕ. Once the voltage of the nonvolatile memory device reaches the threshold voltage Vₜₕ, the current of the nonvolatile memory device may rapidly increase. Thereafter, if the voltage of the nonvolatile memory device reaches the write voltage Vₚ and then a voltage higher than the threshold voltage Vₜₕ is applied to the nonvolatile memory device, the nonvolatile memory device may be placed in the NDR state, i.e., the current of the nonvolatile memory device may decrease according to the voltage applied thereto. Thereafter, if a voltage higher than the erase voltage Vₑ is applied to the nonvolatile memory device, the current of the nonvolatile memory device may slowly increase according to the voltage applied thereto, as illustrated in FIG. 6. In this case, the same mechanism as that described above with reference to FIGS. 5A through 5G may be applied to the nonvolatile memory device because the nonvolatile memory device has a symmetrical structure.

Referring to FIG. 4, if a voltage of 2 V is applied to the nonvolatile memory device when the nanocrystals 40 are yet to be charged with carriers, a current of about 2×10⁻⁵ may flow in the nonvolatile memory device. If the voltage of 2 V is applied to the nonvolatile memory device when the nanocrystals 40 are fully charged with carriers, a current of about 5×10⁻⁴ may flow in the nonvolatile memory device. If the voltage of 2 V is applied to the nonvolatile memory device when the nanocrystals 40 are partially charged with carriers, a current of about 1×10⁻⁴ may flow in the nonvolatile memory device. This bistable conduction property enables the nonvolatile memory device to perform the functions of a typical nonvolatile memory device such as write, read and erase functions.

If the write voltage Vₚ is applied to the nonvolatile memory device, carriers may accumulate in the nanocrystals 40, and thus, a logic high value (Iₒₙ) of 1 may be written to the nonvolatile memory device. The write voltage Vₚ may be within a range of about 3.5-4.5 V, but the present invention is not restricted to this. That is, the write voltage Vₚ may be within a range of about 2-6 V. Once data is written to the nonvolatile memory device, the data is never erased even when the nonvolatile memory device is powered off, as illustrated in FIG. 7.

Thereafter, if the erase voltage Vₑ is applied to the nonvolatile memory device, the carriers accumulated in the nanocrystals 40 may be discharged, and thus the data written to the nonvolatile memory device may be erased and thus replaced with a logic low value (I_{off}) of 0. The erase voltage Vₑ may be about 7.5 V or higher. Once the data written to the nonvolatile memory device is erased, the nonvolatile memory device maintains its state even after being powered off, as illustrated in FIG. 7.

If an intermediate write voltage, i.e., the NDR voltage V_{NDR}, is applied to the nonvolatile memory device, the nanocrystals 40 may be partially charged with carriers, and thus, a data value between the logic high value (Iₒₙ) and the logic low value (I_{off}) may be written to the nonvolatile memory device. The NDR voltage V_{NDR} may be within a range of about 5-7.5 V, but the present invention is not restricted to this. That is, the NDR voltage V_{NDR} may be within a range of about 3-8 V. Various currents may be provided between the first and third currents Iₒₙ and I_{off} according to the magnitude of the NDR voltage V_{NDR}. Thus, it is possible to realize multi-level cells (MLCs). In particular, as the higher the ratio of the first and third currents Iₒₙ and I_{off} increases, the number of MLCs that can be provided increases.

If a read voltage Vᵣ is applied to the nonvolatile memory device, the current of the nanocrystals 40 may considerably vary according to whether and how much the nanocrystals 40 are charged with carriers. Then, data written to the nonvolatile memory device may be read by analyzing the variation in the current of the nanocrystals 40. More specifically, if the variation in the current of the nanocrystals 40 is less than a reference value, it may be determined that no data has been written to the nanocrystals 40, and a data value of 0 may be read from the nonvolatile memory device. If the variation in the current of the nanocrystals 40 is greater than a reference value, it may be determined that data has been written to the nanocrystals 40, and a data value of 1 may be read from the nonvolatile memory device. If the variation in the current of the nanocrystals 40 is greater than the reference value and is less than when the data value of 1 is read from the nonvolatile memory device, it is determined that data has been partially written to the nanocrystals 40, and a data value corresponding to an intermediate state may be read from the nonvolatile memory device. The read voltage Vᵣ may be within a range of about 0.1-2.5 V, but the present invention is not restricted to this. That is, the read voltage Vᵣ may be within a range of about 0.1-3.5 V. In this manner, it is possible to perform the functions of an MLC memory device.

The above-mentioned logic values may be altered according to the direction of a current flow.

The formation and the dispersion of the nanocrystals 40 in the conductive organic layer 30 will hereinafter be described in detail.

The conductive organic layer 30 may be formed of PVK, and the nanocrystals 40 may be formed of Au.

The following method may be used to form a conductive organic material having nanocrystals dispersed therein through spin coating. A first solution is prepared by mixing 1.5 g of tetraoctylammonium bromide (TOAB) with 80 ml of toluene at room temperature and stirring the mixture until the TOAB completely dissolves in the toluene. A second solution is prepared by mixing 0.31 g of gold (III) chloride trihydrate (HAuCl₄.3H₂O) with 25 ml of deionized water and stirring the mixture until the gold (III) chloride trihydrate completely dissolves in the deionized water. Then, the first and second solutions are mixed, and the mixture of the first and second solutions is strongly stirred so as to not cause phase separation. Thereafter, if the color of the mixture of the first and second solutions changes, the mixture of the first and second solutions may be preserved at room temperature until phase separation occurs. Once phase separation occurs in the mixture of the first and second solutions, the supernatant of the mixture of the first and second solutions, i.e., the toluene solution, is separated from the mixture of the first and second solutions, and the remainder of the mixture of the first and second solutions is abandoned.

A surfactant processed with a stabilizer, e.g., thiol processed with carbazole, is added to the separated toluene solution. Thiol has high affinity for Au nanocrystals. Thiol is processed with carbazole so as to be able to be well dispersed in PVK, which is the raw material of a conductive organic layer. Thiol may be processed with carbazole so that the molar ratio of thiol and gold chloride ion (AuCl₄) can become 1:2. After the addition of thiol processed with carbazole, the toluene solution may be stirred for 10 minutes in order to cause the thiol to react with Au nanocrystals, to prevent the agglomeration of the Au nanocrystals, and to properly disperse the Au nanocrystals.

Thereafter, a third solution is prepared by mixing 0.38 g of sodium borohydride (NaBH₄) with 25 ml of deionized water and stirring the mixture until the sodium borohydride completely dissolves in the deionized water. Thereafter, the third solution is mixed with the toluene solution, and the mixture of the third solution and the toluene solution is stirred for about 3 hours, and particularly, for about 2-10 hours.

In order to prevent the breakdown of a conductive organic material and further reaction of the mixture of the third solution and the toluene solution, the mixture of the third solution and the toluene solution is dried at a temperature of about 50° C., the dried mixture is added to 30 ml of chloroform, and the resulting solution is dispersed using ultrasonic waves. Finally, the dispersed solution is mixed with PVK, and the mixture is stirred until the PVK completely dissolves in the chloroform. In this manner, it is possible to form a conductive organic material having nanocrystals dispersed therein.

However, the formation and the dispersion of the nanocrystals 40 are not restricted to the method set forth herein.

A set of processing conditions for the manufacture of a nonvolatile memory device having the above-mentioned bistable conduction property and a method of manufacturing the nonvolatile memory device will hereinafter be described in detail.

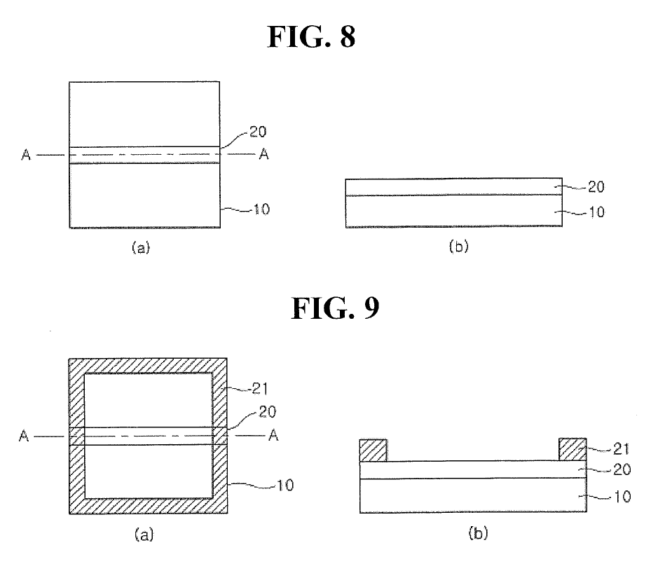

FIGS. 8 through 11 illustrate diagrams for explaining a method of manufacturing a nonvolatile memory device according to an embodiment of the present invention. More specifically, FIGS. 8(a), 9(a), 10(a), and 11(a) illustrate plan views for explaining a method of manufacturing a nonvolatile memory device according to an embodiment of the present invention, and FIGS. 8(b), 9(b), 10(b), and 11(b) illustrate cross-sectional views taken along line A-A of FIGS. 8(a), 9(a), 10(a), and 11(a).

Referring to FIG. 8, a lower conductive layer 20 is formed on a substrate 10. More specifically, the lower conductive layer 20 may be formed as a straight line by using an evaporation method. The substrate 10 may be a silicon substrate or a glass substrate, and a dielectric layer may be additionally deposited on the substrate 10. The dielectric layer may be an oxide layer or a nitride layer.

Thereafter, the substrate 10 is loaded in a chamber (not shown) for a metal deposition, and a portion of the substrate 10 on which the lower conductive layer 20 is to be formed is exposed by using a first shadow mask (not shown). Thereafter, the lower conductive layer 20 is formed on the exposed portion of the substrate 10 by evaporating a metal at a temperature of about 1000 to 1500° C. and at a deposition rate of about 1 to 10 Å/s while maintaining the pressure in the chamber at a range of about 5×10⁻⁷ to 5×10⁻⁵ Pa. The lower conductive layer 20 may be formed of Al to a thickness of about 50-100 nm. The lower conductive layer 20 may be formed as a horizontal straight line. A rinsing operation may be performed before or after the deposition of the lower conductive layer 20 on the substrate 10.

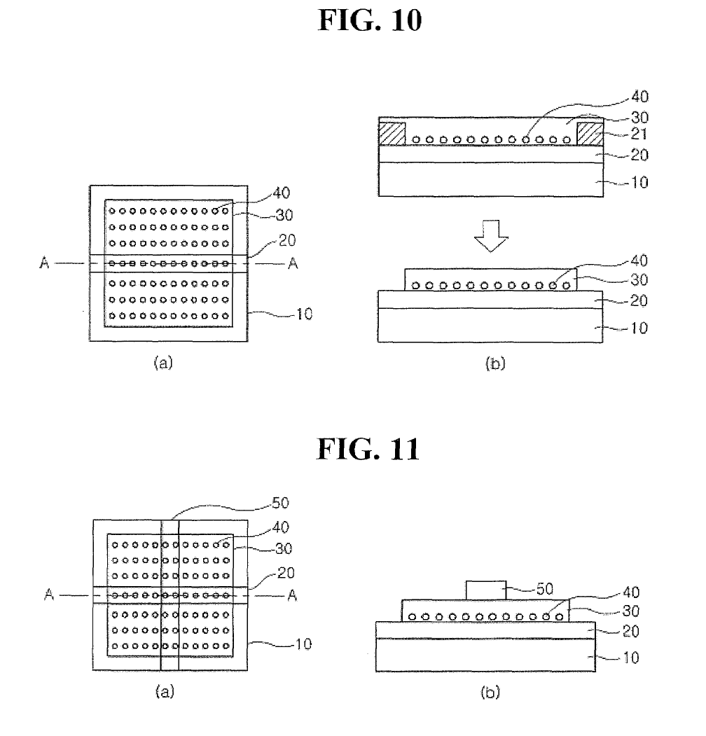

Referring to FIGS. 9 and 10, a conductive organic layer 30 is formed on the substrate 10, on which the lower conductive layer 20 is formed. More specifically, mask patterns 21 that expose a portion of the substrate 10 on which the conductive organic layer 30 is to be formed is formed on the substrate 10, and the substrate 10 is coated with a conductive organic material by using spin coating. Thereafter, the mask patterns 21 and portions of the conductive organic material on the mask patterns 21 are removed, thereby forming the conductive organic layer 30, which overlaps part of the lower conductive layer 20.

The mask patterns 21 may be formed of a material having high etching selectivity to the conductive organic material. For example, the mask patterns 21 may include an oxide layer or a nitride layer. Alternatively, the mask patterns 21 may include a photosensitive film, and this will hereinafter be described in further detail.

Photosensitive film patterns 21 that expose the portion of the substrate 10 on which the conductive organic layer 30 is to be formed may be formed by patterning a photosensitive film. More specifically, a photosensitive film is formed on the substrate 10. The photosensitive may be formed on the substrate 10 by rotating the substrate 10 at about 500-4000 rpm using spin coating. For example, the photosensitive film may be uniformly formed on the substrate 10 by dropping a photoresist solution onto the substrate 10 while rotating the substrate 10 at about 1000 rpm and then increasing the rotation speed of the substrate 10 to about 3000 rpm. Alternatively, the photosensitive film may be uniformly formed by dropping a photoresist solution onto the substrate 10 and then rotating the substrate 10.

Thereafter, a baking operation is performed on the photosensitive film at a temperature of about 100-150° C. for about 1 to 10 minutes. Thereafter, a lithography operation for forming a mask is performed. During the lithography operation, various types of beams may be used. More specifically, ultraviolet (UV) rays may be used during the lithography operation. The photosensitive film may be patterned through an etching operation, thereby forming the photosensitive film patterns 21, which expose the portion of the substrate 10 on which the conductive organic layer 30 is to be formed. The etching operation may be a wet etching operation that involves the use of a chemical solution such as an acetone solution. The etching operation may be performed for about 45 seconds to 60 seconds.

Due to the properties of the photosensitive film, either light-exposed portions or non-light-exposed portions of the photosensitive film may be etched away during the etching operation. During the lithography operation, light may be irradiated on a portion of the photosensitive film on which the conductive organic layer 30 is to be formed. Then, the light-exposed portion of the photosensitive portion may be removed, thereby forming the photosensitive film patterns 21. A rinsing operation may be performed after the formation of the photosensitive film patterns 21.

Thereafter, a conductive organic material having nanocrystals dispersed therein may be applied on the entire surface of the substrate 10 by using spin coating or other technique, the selection of which will be with the skill of one in the art. Thereafter, the photosensitive film patterns 21 and portions of the conductive organic material on the photosensitive film patterns 21 may be removed using a lift-off operation, thereby forming the conductive organic layer 30. The conductive organic material may be PVK or PS. Alternatively, PVK or PS may be mixed with a solvent such as chloroform, and the mixture may be used to form the conductive organic layer 30.

In the embodiment of FIGS. 8 through 11, a conductive organic material such as a PVK solution including nanocrystals 40 may be applied on the substrate 10 by using spin coating. The conductive organic material may be applied on the substrate 10 while rotating the substrate 10 at about 1500-3000 rpm. More specifically, the conductive organic material may be dropped onto the substrate 10 while rotating the substrate 10 at about 2000 rpm, and then the substrate 10 may be further rotated for about 50 to 100 seconds so that the conductive organic material can be uniformly applied on the substrate 100. Thereafter, a baking operation may be performed on the conductive organic material at a temperature of about 100-150° C. for about 1-10 minutes. Alternatively, the conductive organic material may be applied on the substrate 10, and then the substrate 10 may be rotated so that the conductive organic material can be uniformly distributed.

Thereafter, the photosensitive film patterns 21 and portions of the conductive organic material on the photosensitive film patterns 21 are removed by performing a lift-off operation. As a result, the conductive organic layer 30 is formed. Referring to FIG. 10(b), when the conductive organic material is applied on the substrate 10 by using spin coating, most of the conductive organic material is disposed on a portion of the substrate 10 exposed between the photosensitive film patterns 21, and the remaining organic material is disposed on each of the photosensitive film patterns 21. Thereafter, the photosensitive film patterns 21 are removed by performing a strip operation. Then, portions of the conductive organic material on the photosensitive film patterns 21 are removed along with the photosensitive film patterns 21. As a result, the conductive organic layer 30 is formed on a portion of the substrate 10 where the photosensitive film patterns 21 are not formed.

The conductive organic layer 30 overlaps part of the lower conductive layer 20. Referring to FIG. 10, the conductive organic layer 30 may be formed as a rectangle, and the lower conductive layer 20 may extend across the middle of the conductive organic layer 30. However, the present invention is not restricted to this. That is, the conductive organic layer 30 may be formed as a circle, an ellipse, or a polygon other than a rectangle.

In the embodiment of FIGS. 8 through 11, the conductive organic layer 30 is formed of PVK to a thickness of about 30-100 nm. The conductive organic layer 30 includes the nanocrystals 40 therein.

Referring to FIG. 11, an upper conductive layer 50 is formed on the substrate 10, on which the conductive organic layer 30 is formed. The upper conductive layer 50 may be formed as a straight line that perpendicularly intersects the lower conductive layer 30.

For this, the substrate 10 may be loaded in a chamber for the deposition of a metal, and a portion of the first conductive organic layer 30 and a portion of the substrate 10 on which the upper conductive layer 50 is to be formed are exposed by a second shadow mask. In this manner, the upper conductive layer 50 can be formed so that the conductive organic layer 30 can be disposed in the overlapping area of the upper conductive layer 50 and the lower conductive layer 20.

Thereafter, the upper conductive layer 50 is formed on the exposed portion of the conductive organic layer 30 and the exposed portion of the substrate 10 of the substrate 10 by evaporating a metal at a temperature of about 1000 to 1500° C. and at a deposition rate of about 1 to 10 Å/s while maintaining the pressure in the chamber at a range of about 5×10⁻⁷ to 5×10⁻⁵ Pa. The upper conductive layer 50 may be formed of Al to a thickness of about 60-100 nm. The lower conductive layer 20 may be formed as a vertical straight line. Then, it is possible to provide a nonvolatile memory device that has 4F² memory cells and can thus provide high integration density. A rinsing operation may be performed before or after the deposition of the lower conductive layer 20 on the substrate 10.

Thereafter, a metal interconnection operation may be performed in order to connect each of the upper conductive layer 50 and the lower conductive layer 20 to an external electrode. In addition, a passivation operation for protecting a memory device may be performed. In the embodiment of FIGS. 8 through 11, the conductive organic layer 30 is formed of PVK. Thus, it is possible to prevent the properties of the conductive organic layer 30 from being altered during a passivation operation, which involves performing thermal treatment at a high temperature of about 300° C.

The present invention, however, is not restricted to the embodiment of FIGS. 8 through 11. The lower and upper conductive layers 20 and 50, the conductive organic layer 30, and the nanocrystals 40 may be formed using various methods, other than thermal evaporation. For example, the lower and upper conductive layers 20 and 50, the conductive organic layer 30, and the nanocrystals 40 may be formed using electron-beam (E-beam) deposition, sputtering, chemical vapor deposition (CVD) or atomic-layer deposition (ALD). The lower and upper conductive layers 20 and 50 and the conductive organic layer 30 may be formed through patterning. That is, each of the lower and upper conductive layers 20 and 50 and the conductive organic layer 30 may be formed by depositing a conductive material on the substrate 10 and performing an etching operation on the conductive material.

In the embodiment of FIGS. 8 through 11, the conductive organic layer 30 may be formed of PVK, and the nanocrystals 40 are formed of Au. In this manner, it may be possible to manufacture a nonvolatile memory device including a conductive organic layer having nanocrystals dispersed therein.

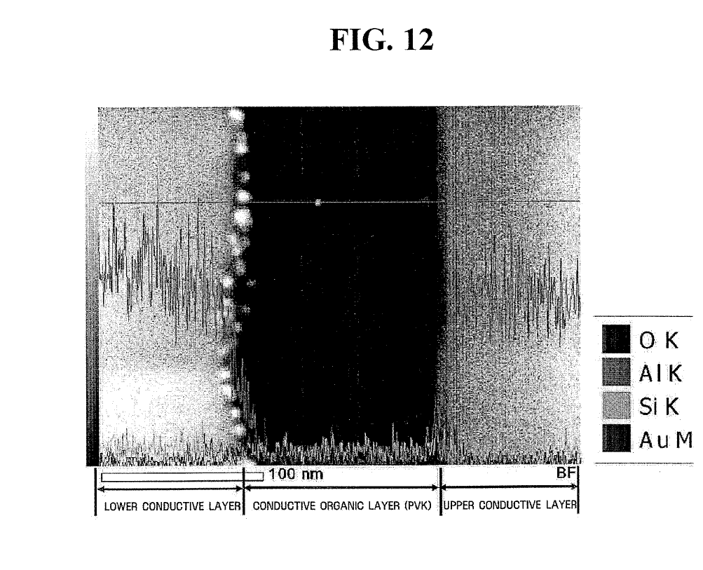

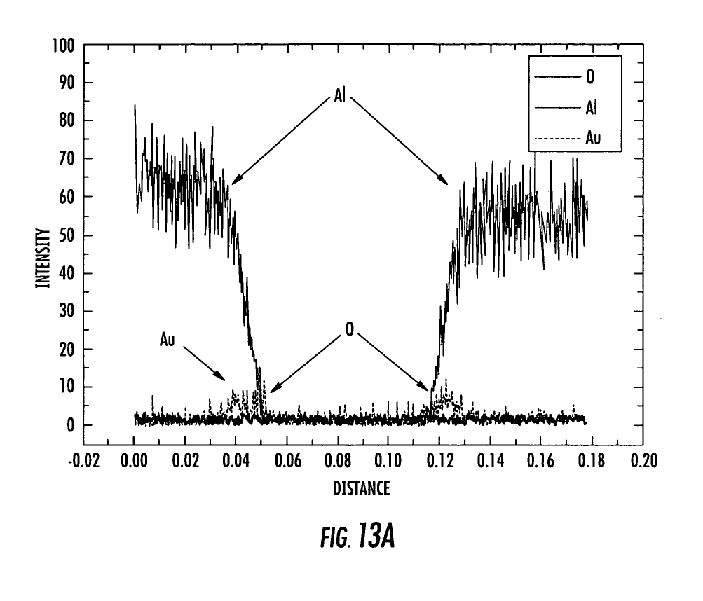

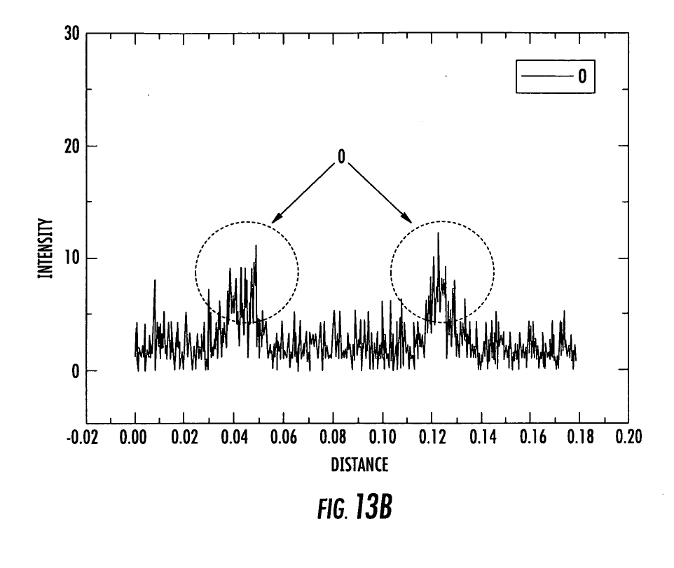

FIG. 12 shows a TEM image of a memory device obtained by the method of the embodiment of FIGS. 8 through 11, and FIGS. 13A through 13D illustrate energy dispersive spectroscopy (EDS) images of the distributions of various components of the memory device illustrated in FIG. 12.

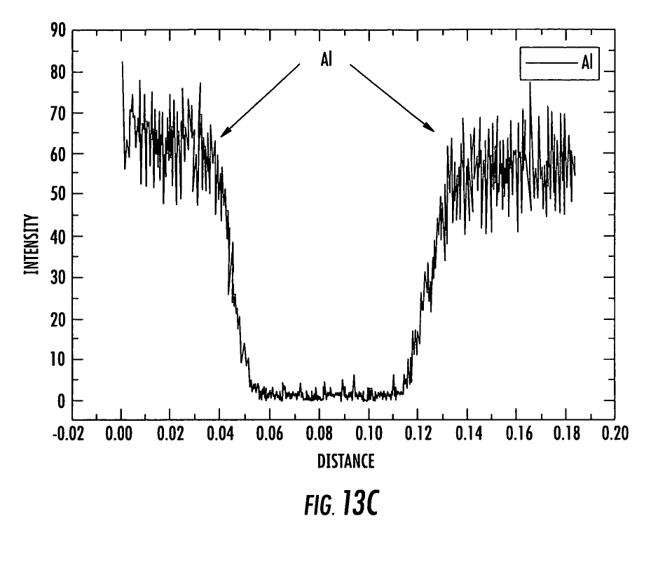

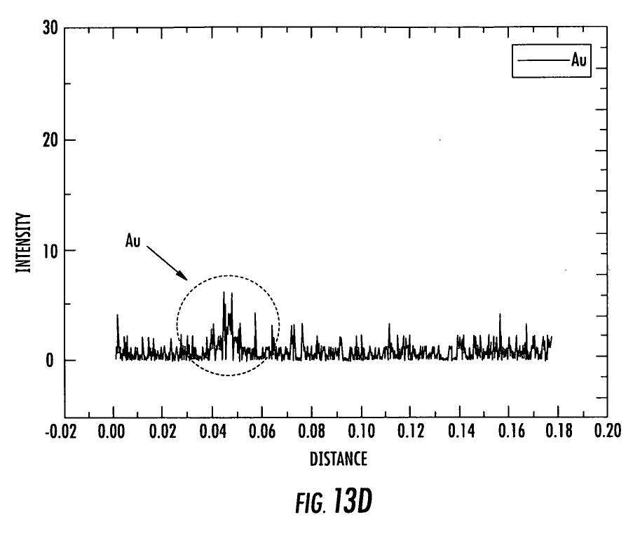

Referring to FIG. 12, a conductive layer may be formed between upper and lower conductive layers, and nanocrystals may be formed in the conductive organic layer. FIG. 13A illustrates the distributions of all components of the memory device illustrated in FIG. 12, FIG. 13B illustrates the distribution of oxygen (O), FIG. 13C illustrates the distribution of Al, and FIG. 13D illustrates the distribution of Au.

Referring to FIGS. 12 through 13D, Al, which is the material of upper and lower conductive layers, is distributed on the top and the bottom of a conductive organic layer, Au, which is the material of nanocrystals, is distributed in the conductive organic layer near the lower conductive layer, and O is distributed among the conductive organic layer and the upper and lower conductive layers, but not in the conductive organic layer.

As described above, according to the present invention, it is possible to provide a highly-integrated memory device that consumes less power due to having conductive organic layers and nanocrystals between the conductive organic layers, provides high operating speed and has 4F² memory cells.

According to the present invention, it is possible to repeatedly perform read, write and erase operations with the use of the bistable conduction property of a conductive organic material and to maintain data present in each memory cell of a memory device even when the memory device is powered off.

According to the present invention, it is possible to realize an MLC memory device by using the bistable conduction property of a conductive organic material.

According to the present invention, it is possible to provide the thermal stability of a memory device by using a conductive organic polymer.

According to the present invention, it is possible to reduce the time required to deposit a conductive organic layer by forming a conductive layer using spin coating.

According to the present invention, it is possible to form a conductive organic layer in various shapes by using mask patterns that can be formed on a substrate in various shapes.

According to the present invention, it is possible to facilitate the adjustment of the size and the concentration of nanocrystals by dispersing nanocrystals in a conductive organic polymer.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A nonvolatile memory device which is convertible among a high current state, an intermediate current state, and a low current state, said device comprising:
upper and lower conductive layers;
a conductive organic layer comprising a conductive organic polymer and which is formed between the upper and lower conductive layers and has a bistable conduction property; and
nanocrystals are formed in the conductive organic layer.

2. The nonvolatile memory device of claim 1, wherein the intermediate current state comprises multi-level current states corresponding to the magnitude of the negative differential resistance (NDR) voltage.

3. The nonvolatile memory device of claim 1, wherein the high-current state occurs at a read voltage, after the application of a write voltage, the intermediate current state occurs at the read voltage, after the application of a negative differential resistance (NDR) voltage, and the low current state occurs at the read voltage, after the application of an erase voltage.

4. The nonvolatile memory device of claim 3, wherein the NDR voltage is higher than the write voltage, and the erase voltage is higher than the NDR voltage.

5. The nonvolatile memory device of claim 1, wherein the nanocrystals are spaced apart from each other.

6. The nonvolatile memory device of claim 1, wherein the nanocrystals have uniform sizes.

7. The nonvolatile memory device of claim 1, wherein the conductive organic polymer is poly-N-vinylcarbazole (PVK) or polystyrene (PS).

8. The nonvolatile memory device of claim 1, wherein the nanocrystals comprise at least one of Au, Pt, Ag, Ni, Cu and an alloy thereof.

9. A method of manufacturing a nonvolatile memory device, the method comprising:
forming a lower conductive layer on a substrate;
forming a conductive organic layer having nanocrystals dispersed therein on the substrate using spin coating; and
forming an upper conductive layer on the conductive organic layer.

10. The method of claim 9, the method further comprising dispersing the nanocrystals in the conductive organic layer before the forming of the conductive layer.

11. The method of claim 9, wherein the forming of the conductive organic layer comprises:
forming mask patterns on the substrate;
applying a conductive organic material having the nanocrystals dispersed therein on the substrate using spin coating; and
removing the mask patterns and portions of the conductive organic material on the mask patterns.

12. The method of claim 11, wherein the applying of the conductive organic material comprises applying a liquid-phase conductive organic material on the substrate while rotating the substrate at about 1000-3000 rpm.

13. The method of claim 11, wherein the applying of the conductive organic material comprises applying a liquid-phase conductive organic material on the substrate and then rotating the substrate at about 1000-3000 rpm.

14. The method of claim 9, wherein the conductive organic material is poly-n-vinylcarbazole (PVK) or polystyrene (PS) mixed with a solvent.
